(19) United States
(12) Patent Application Publication
(10) Pub. No.: US 2012/0280276 A1
(43) Pub. Date: Nov. 8, 2012

(54) Single Crystal Ge On Si

(76) Inventors: Rytis Dargis, Fremont, CA (US); Erdem Arkun, San Carlos, CA (US); Andrew Clark, Los Altos, CA (US); Michael Lebby, Apache Junction, AZ (US)

(21) Appl. No.: 13/425,079

(22) Filed: Mar. 20, 2012

Related U.S. Application Data
(60) Provisional application No. 61/483,648, filed on May 7, 2011.

(51) Int. Cl. H01L 21/20; H01L 29/165

(52) U.S. Cl. 257/190; 438/479; 257/E29.085; 257/E21.09

(57) ABSTRACT

A single crystal germanium-on-silicon structure includes a single crystal silicon substrate. A single crystal layer of gadolinium oxide is epitaxially grown on the substrate. The gadolinium oxide has a cubic crystal structure and a lattice spacing approximately equal to the lattice spacing or a multiple of the single crystal silicon. A single crystal layer of lanthanum oxide is epitaxially grown on the gadolinium oxide with a thickness of approximately 12 nm or less. The lanthanum oxide has a lattice spacing approximately equal to the lattice spacing or a multiple of single crystal germanium and a cubic crystal structure approximately similar to the cubic crystal structure of the gadolinium oxide. A single crystal layer of germanium with a (111) crystal orientation is epitaxially grown on the layer of lanthanum oxide.

### CROSS-REFERENCE TO RELATED APPLICATION

This application claims the benefit of U.S. Provisional Patent Application No. 61/483,648, filed 7 May 2011.

### FIELD OF THE INVENTION

This invention relates to the epitaxial growth of single crystal germanium on a silicon substrate.

### BACKGROUND OF THE INVENTION

Layers of single crystal germanium formed on silicon substrates are applicable for electronic and photonic devices. However, because of the relatively large lattice constant mismatch (4.2%) between silicon and germanium the straightforward or direct growth of germanium on silicon leads to or results in the formation of a rough germanium layer with high density dislocations. The rough layer with high density dislocations makes such material virtually useless for the fabrication of electronic and photonic devices. To date many different attempts to grow germanium on silicon have been tried but these attempts generally are either very complicated or not very efficient.

It would be highly advantageous, therefore, to remedy the foregoing and other deficiencies inherent in the prior art.

Accordingly, it is an object of the present invention to provide new and improved method for growing a single crystal germanium layer on a silicon substrate.

It is another object of the present invention to provide a silicon substrate with a single crystal layer of germanium formed thereon.

### SUMMARY OF THE INVENTION

Briefly, to achieve the desired objects of the instant invention in accordance with a preferred embodiment thereof, a single crystal germanium-on-silicon structure includes a single crystal silicon substrate having a cubic crystal structure. A first layer of a first single crystal rare earth oxide is epitaxially grown on the substrate. The first single crystal rare earth oxide has a cubic crystal structure and a lattice spacing approximately equal to the lattice spacing or a multiple of the single crystal silicon. A second layer of a second single crystal rare earth oxide is epitaxially grown on the first layer of the first single crystal rare earth oxide. The second crystal rare earth oxide has a lattice spacing approximately equal to the lattice spacing or a multiple of single crystal germanium and a cubic crystal structure approximately similar to the cubic crystal structure of the first single crystal rare earth oxide. A single crystal layer of germanium is epitaxially grown on the second layer of the second single crystal rare earth oxide.

The desired objects of the instant invention are further achieved in accordance with a specific embodiment thereof in which a single crystal germanium-on-silicon structure includes a single crystal silicon substrate. A single crystal layer of gadolinium oxide is epitaxially grown on the substrate. The gadolinium oxide has a cubic crystal structure and a lattice spacing approximately equal to the lattice spacing or a multiple of the single crystal silicon. A single crystal layer of lanthanum oxide is epitaxially grown on the gadolinium oxide with a thickness of approximately 12 nm or less. The lanthanum oxide has a lattice spacing approximately equal to the lattice spacing or a multiple of single crystal germanium and a cubic crystal structure approximately similar to the cubic crystal structure of the gadolinium oxide. A single crystal layer of germanium with a (111) crystal orientation is epitaxially grown on the layer of lanthanum oxide.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 is a simplified layer diagram illustrating an example of a single crystal germanium layer grown on a silicon substrate in accordance with the present invention;

FIG. 2 is a chart illustrating the crystal lattice relationship between oxides of various lanthanides and silicon and germanium;

FIG. 3 is a simplified layer diagram illustrating a first step in the method for growing a single crystal germanium layer on a silicon substrate;

FIG. 4 is a simplified layer diagram illustrating a second step in the method for growing a single crystal germanium layer on a silicon substrate;

FIG. 5 is a simplified layer diagram illustrating a third step in the method for growing a single crystal germanium layer on a silicon substrate; and

FIG. 6 is a simplified layer diagram illustrating a final step in the method for growing a single crystal germanium layer on a silicon substrate.

### DETAILED DESCRIPTION OF THE FIGURES

Referring specifically to FIG. 1, a simplified layer diagram illustrates an example of a structure 10, including a single crystal germanium layer 18 grown on a silicon substrate 12 in accordance with the present invention. It will be understood that silicon substrate 12 is a standard well know single crystal wafer or portion thereof generally known and used in the semiconductor industry. Generically, the invention includes epitaxially growing a first layer 14 of a first single crystal rare earth oxide material with a lattice constant that is close to the lattice constant of silicon. A second step includes epitaxially growing on first layer 14 a second layer 16 of a second single crystal rare earth oxide material with a lattice constant that is close to the lattice constant of germanium. The first and second rare earth oxide materials are selected to substantially adapt crystal lattice structures to each other at the juncture so that a large crystal mismatch does not occur. Finally, single crystal layer 18 of germanium is epitaxially grown on the second layer 16 of second single crystal rare earth oxide material. Since second layer 16 of second single crystal rare earth oxide material has a lattice constant that is close to the lattice constant of germanium, a substantially flat layer of germanium is produced.

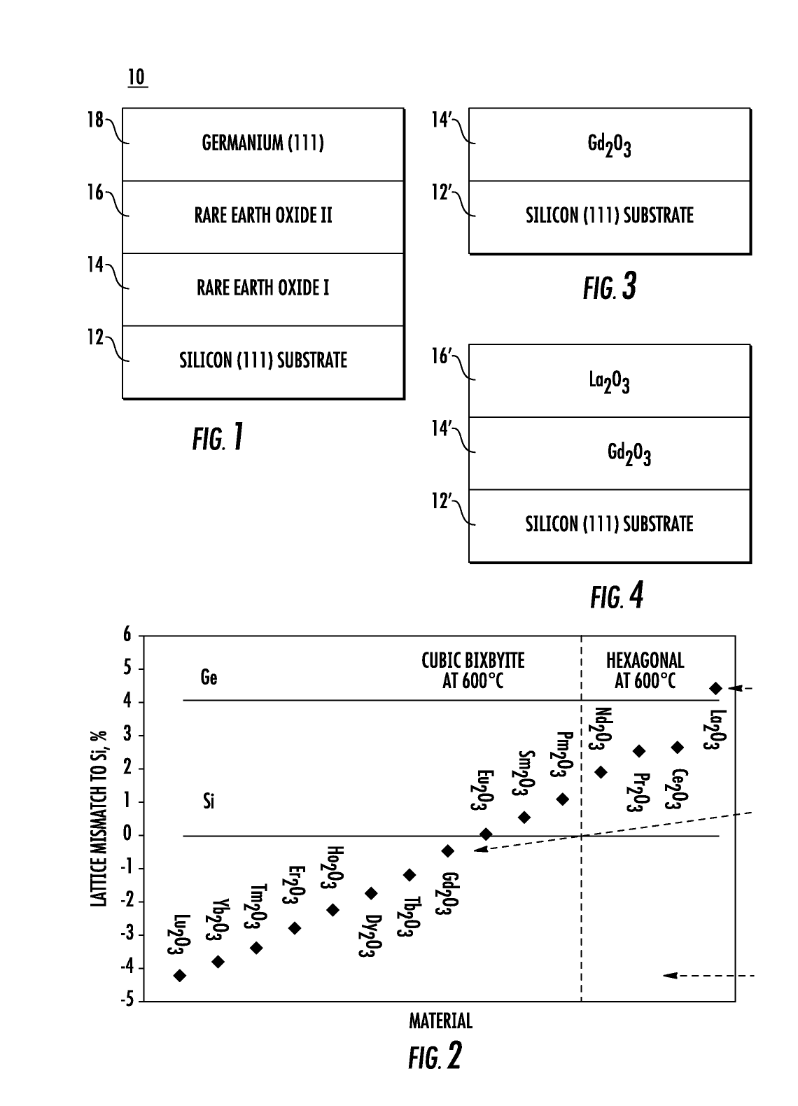

Referring additionally to FIG. 2, a chart illustrating the crystal lattice relationship between the various oxides of lanthanides and silicon and germanium is provided. As can be seen from this chart, the crystal lattice of gadolinium oxide is cubic, the same as silicon, and has a mismatch of only about a negative 0.5% with the crystal lattice of silicon. Also, it has been found that lanthanum oxide, which normally has a hexagonal crystal lattice, can be grown with a cubic crystal lattice that has a mismatch of only about a positive 0.5% with the crystal lattice of germanium. It will be understood that other combinations of lanthanide oxides might be provided to fabricate the generic structure illustrated in FIG. 1.

A specific method of forming the generic structure illustrated in FIG. 1 is set forth below beginning with a first step as illustrated in FIG. 3. A silicon substrate 12′ with a (111) crystal orientation is provided and a layer of gadolinium oxide (Gd₂O₃) is epitaxially grown on the surface. Because the crystal lattices are relatively closely matched (−0.5% mismatch) a flat high crystal quality cubic Gd₂O₃ layer 14′ is grown on substrate 12′.

Referring now to FIG. 4, a second step in the formation of a specific embodiment of structure 10 is illustrated. A thin layer of lanthanum oxide (La₂O₃) is epitaxially grown on the surface of Gd₂O₃ layer 14′. It has been found that, while lanthanum oxide has a hexagonal lattice structure at 600° C., when it is grown at a low growth rate and a moderate growth temperature (700° C.) the La₂O₃ adopts the crystal of the cubic Gd₂O₃. However, the lattice of La₂O₃ layer 16′ is under compressive stress in the lateral direction, because Gd₂O₃ has a smaller crystal lattice. It has also been found that at thicknesses higher than approximately 12 nm the La₂O₃ lattice starts to transform to a hexagonal lattice and layer 16′ becomes rough. In this embodiment, the gadolinium oxide serves as a template layer for the growth of the second rare earth oxide layer. The low growth rate and optimal growth temperature are essential for the formation of the cubic lattice lanthanum oxide layer. Thus, it is preferred or desirable to epitaxially grow La₂O₃ layer 16′ at approximately 700° C.±20° C. and with a thickness of approximately 12 nm or less.

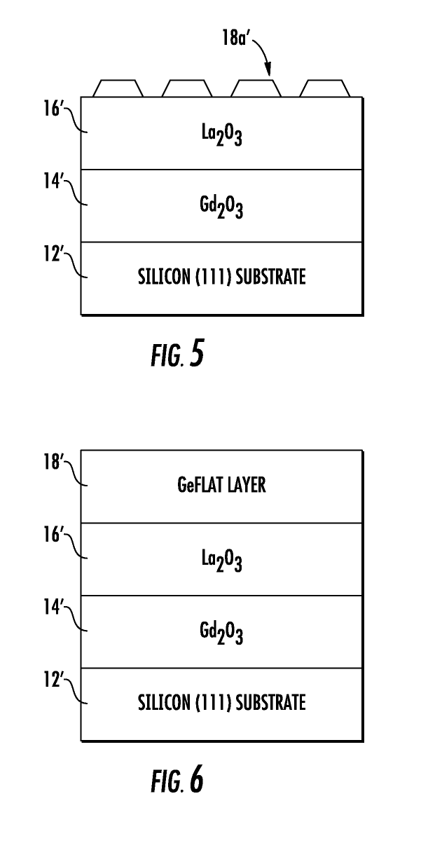

Referring now to FIG. 5, a third or final step in the formation of the specific embodiment of structure 10 is illustrated wherein Germanium is epitaxially grown on the surface of La₂O₃ layer 16′. The higher surface energy of germanium than that of lanthanum oxide results in a Volmer-Weber 3-dimensional growth mode. That is, at the beginning single crystal (111) oriented germanium islands 18a′ grow on the surface of La₂O₃ layer 16′. Referring additionally to FIG. 6, as the germanium growth continues island 18a′ conglomerate, fill-in or smooth out resulting in a relatively flat single crystal germanium (111) layer. Measuring the surface roughness determined that an RMS roughness of approximately 5.66 nm or less was achieved.

Thus, a new and improved method for growing a single crystal germanium layer on a silicon substrate has been disclosed. The present invention provides a silicon substrate with a single crystal layer of germanium formed thereon. The formation of a single crystal layer of germanium on a silicon substrate is relatively easy to achieve and results in a relatively flat high crystal quality germanium layer. While a specific embodiment of the invention is described and illustrated, it will be understood that other embodiments may be devised from other materials while using the same generic structure.

Various changes and modifications to the embodiment herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A single crystal germanium-on-silicon structure comprising:
a single crystal silicon substrate, the single crystal silicon having a cubic crystal structure and a lattice spacing;
a first layer of a first single crystal rare earth oxide epitaxially grown on the substrate, the first single crystal rare earth oxide having a cubic crystal structure and a lattice spacing approximately equal to the lattice spacing or a multiple of the single crystal silicon;
a second layer of a second single crystal rare earth oxide epitaxially grown on the first layer of the first single crystal rare earth oxide, the second crystal rare earth oxide having a lattice spacing approximately equal to the lattice spacing or a multiple of single crystal germanium, the second crystal rare earth oxide having a cubic crystal structure approximately similar to the cubic crystal structure of the first single crystal rare earth oxide; and
a single crystal layer of germanium epitaxially grown on the second layer of the second single crystal rare earth oxide.

2. A single crystal germanium-on-silicon structure as claimed in claim 1 wherein the first single crystal rare earth oxide includes gadolinium having a −0.5% crystal lattice mismatch with silicon.

3. A single crystal germanium-on-silicon structure as claimed in claim 1 wherein the second single crystal rare earth oxide includes lanthanum having a +0.5% crystal lattice mismatch with germanium.

4. A single crystal germanium-on-silicon structure as claimed in claim 1 wherein the second single crystal rare earth oxide includes a layer of lanthanum oxide with a thickness of approximately 12 nm or less.

5. A single crystal germanium-on-silicon structure as claimed in claim 1 wherein the single crystal silicon substrate has a (111) crystal orientation.

6. A single crystal germanium-on-silicon structure as claimed in claim 1 wherein the single crystal germanium layer has a (111) crystal orientation.

7. A single crystal germanium-on-silicon structure as claimed in claim 1 wherein the single crystal germanium layer has a RMS surface roughness of approximately 5.66 nm or less.

8. A single crystal germanium-on-silicon structure comprising:
a single crystal silicon substrate with a (111) crystal orientation, the single crystal silicon having a cubic crystal structure and a lattice spacing;
a single crystal layer of gadolinium oxide epitaxially grown on the substrate, the gadolinium oxide having a cubic crystal structure and a lattice spacing approximately equal to the lattice spacing or a multiple of the single crystal silicon;
a single crystal layer of lanthanum oxide epitaxially grown on the gadolinium oxide with a thickness of approximately 12 nm or less, the lanthanum oxide having a lattice spacing approximately equal to the lattice spacing or a multiple of single crystal germanium, the lanthanum oxide having a cubic crystal structure approximately similar to the cubic crystal structure of the gadolinium oxide; and
a single crystal layer of germanium with a (111) crystal orientation epitaxially grown on the layer of lanthanum oxide.

9. A single crystal germanium-on-silicon structure as claimed in claim 8 wherein the single crystal germanium layer has a RMS surface roughness of approximately 5.66 nm or less.

10. A method of fabricating a single crystal germanium-on-silicon structure comprising the steps of:
providing a single crystal silicon substrate, the single crystal silicon having a cubic crystal structure and a lattice spacing;
epitaxially growing a first layer of a first single crystal rare earth oxide on the substrate, the first single crystal rare earth oxide having a cubic crystal structure and a lattice spacing approximately equal to the lattice spacing or a multiple of the single crystal silicon;
epitaxially growing a second layer of a second single crystal rare earth oxide on the first layer of the first single crystal rare earth oxide, the second crystal rare earth oxide having a lattice spacing approximately equal to the lattice spacing or a multiple of single crystal germanium, the second crystal rare earth oxide having a cubic crystal structure approximately similar to the cubic crystal structure of the first single crystal rare earth oxide; and
epitaxially growing a single crystal layer of germanium on the second layer of the second single crystal rare earth oxide.

11. A method as claimed in claim 10 wherein the step of epitaxially growing the first layer of the first single crystal rare earth oxide on the substrate includes epitaxially growing a layer of gadolinium oxide.

12. A method as claimed in claim 10 wherein the step of epitaxially growing the second layer of the second single crystal rare earth oxide on the substrate includes epitaxially growing a layer of lanthanum oxide.

13. A method as claimed in claim 12 wherein the step of epitaxially growing the layer of lanthanum oxide includes growing the lanthanum oxide with a thickness of approximately 12 nm or less.

14. A method as claimed in claim 10 wherein the step of epitaxially growing the single crystal germanium layer includes growing the germanium layer with a RMS surface roughness of approximately 5.66 nm or less.

15. A method as claimed in claim 12 wherein the step of epitaxially growing the layer of lanthanum oxide includes growing the lanthanum oxide at approximately 700° C.±20° C.

16. A method of fabricating a single crystal germanium-on-silicon structure comprising the steps of:
providing a single crystal silicon substrate with a (111) crystal orientation, the single crystal silicon having a cubic crystal structure and a lattice spacing;
epitaxially growing a single crystal layer of gadolinium oxide on the substrate, the gadolinium oxide having a cubic crystal structure and a lattice spacing approximately equal to the lattice spacing or a multiple of the single crystal silicon;
epitaxially growing a single crystal layer of lanthanum oxide on the gadolinium oxide with a thickness of approximately 12 nm or less, the lanthanum oxide having a lattice spacing approximately equal to the lattice spacing or a multiple of single crystal germanium, the lanthanum oxide having a cubic crystal structure approximately similar to the cubic crystal structure of the gadolinium oxide, the layer of lanthanum oxide being grown at approximately 700° C.±20° C. with a thickness of approximately 12 nm or less; and
epitaxially growing a single crystal layer of germanium with a (111) crystal orientation on the layer of lanthanum oxide.

17. A method as claimed in claim 16 wherein the step of epitaxially growing the single crystal germanium layer includes growing the germanium layer with a RMS surface roughness of approximately 5.66 nm or less.
